(19) United States
(12) Patent Application Publication
(10) Pub. No.: US 2016/0181091 A1
(43) Pub. Date: Jun. 23, 2016

(54) Methods for Forming Ferroelectric Phases in Materials and Devices Utilizing the Same

(71) Applicant: Intermolecular, Inc., San Jose, CA (US)

(72) Inventors: Sandip Niyogi, San Jose, CA (US); Sergey Barabash, San Jose, CA (US); Federico Nardi, Palo Alto, CA (US); Dipankar Pramanik, Saratoga, CA (US)

(21) Appl. No.: 14/576,853

(22) Filed: Dec. 19, 2014

(51) Int. Cl. H01L 21/02

(52) U.S. Cl. CPC H01L 21/02356

(57) ABSTRACT

Embodiments provided herein describe systems and methods for forming ferroelectric materials. A trench body may be provided. A trench may be formed in the trench body. A dielectric material and a filler material may be deposited within the trench. The filler material may be heated such that a stress is exerted on the dielectric material before the dielectric material is heated to generate a ferroelectric phase within the dielectric material. A non-contiguous layer may be formed above a substrate. A second layer including a high-k dielectric material may be formed above the first layer. The high-k dielectric material may be heated to generate a ferroelectric phase within the high-k dielectric material.

### TECHNICAL FIELD

The present invention relates to semiconductor devices, such as transistors. More particularly, this invention relates to methods for forming ferroelectric materials for use in, for example, semiconductor devices.

### BACKGROUND

As microelectronic devices continue to get smaller and smaller, while performance demands continue to increase, there is an ever growing need for materials with very high dielectric constants (i.e., high-k dielectric materials), such as for gate dielectrics in field-effect transistors.

One possible solution is the use of high-k dielectric materials (e.g., hafnium oxide) in which a ferroelectric state (or phase) has been created. Using conventional processing methods, in order to generate the ferroelectric phase in the material, a high temperature (e.g., 1000° C. or more) must be performed. Such a high temperature anneal is not compatible with advanced logic or memory technologies and often results in the formation of large grain boundaries within the high-k dielectric material, which often results in unstable performance.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with a trench body formed above according to some embodiments.

FIG. 2 is a cross-sectional view of the substrate of FIG. 1 with a trench formed in the trench body.

FIG. 3 is a cross-sectional view of the trench body of FIG. 2 with a first barrier layer formed within the trench.

FIG. 4 is a cross-sectional view of the trench body of FIG. 3 with a supplemental layer formed at the bottom of the trench.

FIG. 5 is a cross-sectional view of the trench body of FIG. 4 with a dielectric layer formed within the trench.

FIG. 6 is a cross-sectional view of the trench body of FIG. 5 with a second barrier layer formed within the trench.

FIG. 7 is a cross-sectional view of the trench body of FIG. 6 with a filler material deposited within the trench.

FIG. 8 is a cross-sectional view of the trench body of FIG. 7 with a transparent layer formed above the filler material and a non-transparent layer formed over the remaining portions of the trench body.

FIG. 9 is a cross-sectional view of the trench body of FIG. 8 illustrating the filler material being expanded.

FIG. 10 is a cross-sectional view of the trench body of FIG. 9 after the transparent layer, the non-transparent layer, and the filler material have been removed.

FIG. 11 is a cross-sectional view of a substrate undergoing a surface treatment process according to some embodiments.

FIG. 12 is a cross-sectional view of the substrate of FIG. 11 with a non-contiguous layer formed above.

FIG. 13 is a cross-sectional view of the substrate of FIG. 12 with a contiguous layer formed above the non-contiguous layer.

FIG. 14 is a cross-sectional view of the substrate of FIG. 13 with additional layers formed above the contiguous layer.

FIG. 15 is a cross-sectional view of a substrate according to some embodiments.

FIG. 16 is a cross-sectional view of the substrate of FIG. 15 with two contiguous layers formed above the substrate and a non-contiguous layer formed above the two contiguous layers.

FIG. 17 is a cross-sectional view of the substrate of FIG. 16 with additional layers formed above the non-contiguous layer.

FIG. 18 is a cross-sectional view of a substrate with a semiconductor device formed above.

FIG. 19 is flow chart of a method for forming a ferroelectric material according to some embodiments.

FIG. 20 is flow chart of a method for forming a ferroelectric material according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide methods for forming or depositing high-k dielectric materials in such a way that ferroelectric phases may be formed without the need for a high temperature annealing process.

In some embodiments, a ferroelectric state is generated within a dielectric material by forming a series of process steps within a trench formed in a matrix or substrate material. Specifically, in some embodiments, a trench is first formed in a trench body (or layer). A dielectric material (e.g., a high-k dielectric material) may then be deposited on at least a side wall of the trench. The trench is then filled with a filler material (e.g., metallic or a polymer) having a high coefficient of thermal expansion (e.g., coefficient of linear thermal expansion). The device is then heated in such a way that the filler material is heated faster than, or at least at a comparable rate as, the dielectric material. Due to the high expansion coefficient of the filler material, a substantial compressive stress is created across the dielectric material before the material is brought to the crystallization temperature. This results in the ferroelectric phase forming during crystallization.

In some embodiments in which a polymer is used as the filer material, the filler material is heated by shining light, such as laser light, localized to the region of the filler material itself (e.g., by blocking the remainder of the device with a non-transparent layer). In some embodiments, infrared (IR) light is used and the wavelength is selected to match the frequency of the known IR-active modes of the polymer.

In some embodiments, high-k dielectric materials are formed using ALD in such a way that a ferroelectric phase may be formed using a lower temperature anneal. This is accomplished by inducing a texture into at least one of the ALD layers in a stack of ALD layers during formation. This texture induces a stress onto at least some of the ALD layers which results in the formation of a ferroelectric phase at lower annealing temperatures (e.g., less than 1000° C., such as 400° C.).

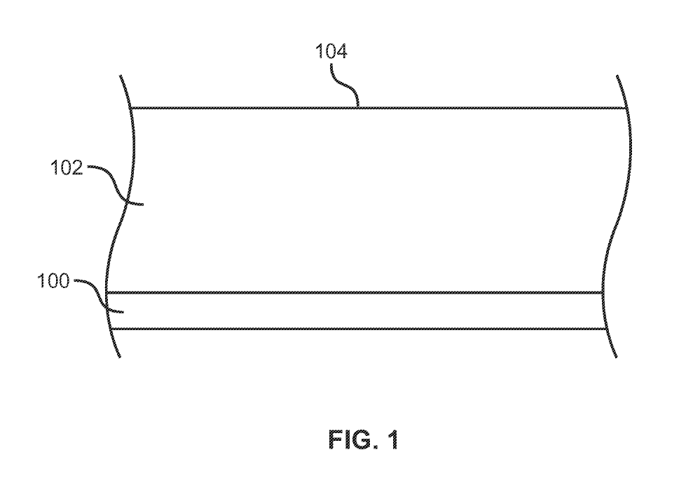

FIGS. 1-10 illustrate a method for forming a ferroelectric material, or generating a ferroelectric phase in a material, according to some embodiments. Referring now to FIG. 1, a substrate 100 is shown, which has a trench layer, or trench body, 102 (i.e., a body or layer in which a trench is formed, as described below) formed thereon, which has an upper surface 104. The substrate 100 may be used to provide support for the trench body 102 and may be made of any suitable material, such as a semiconductor material, a polymer, a ceramic material, glass, etc. In some embodiments, the trench body 102 includes a material with a relatively low coefficient of linear thermal expansion, such as a semiconductor material (e.g., silicon) or a dielectric material, such as silicon oxide or glass (e.g., borosilicate). In some embodiments, the trench body 102 may be used without the substrate 100 (e.g., when the trench body 102 is made of glass), or may be a portion of the substrate 100.

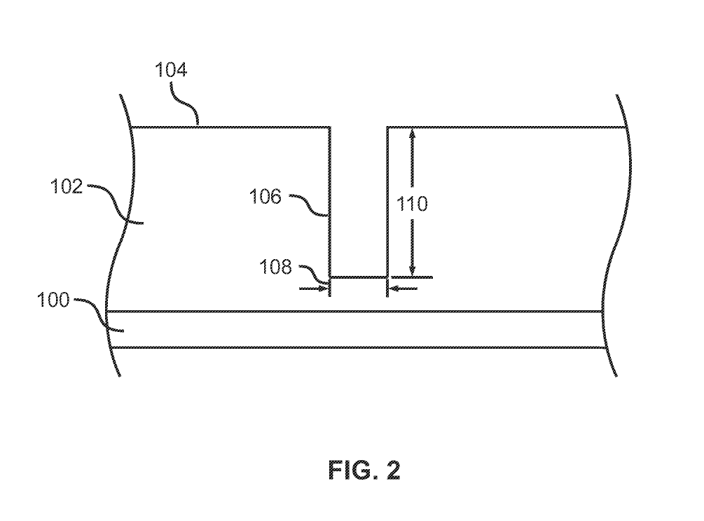

As shown in FIG. 2, a trench 106 is formed in the trench body 102 through the upper surface 104 thereof. The trench 106 may be formed using any suitable process, such an etching process. The trench 106 has a width 108 and a depth (or height) 110. It should be noted that FIG. 2 may not be shown to scale, and that in some embodiments, the depth 110 of the trench 106 is considerably greater than the width 108 of the trench 106, and the overall thickness of the trench body 102 may be considerably greater than the depth 110 of the trench. It should also be understood that although only one trench 106 is shown, additional trenches may be formed in the trench body 102, and the processing steps described below may be performed in/on all of the trenches, perhaps simultaneously.

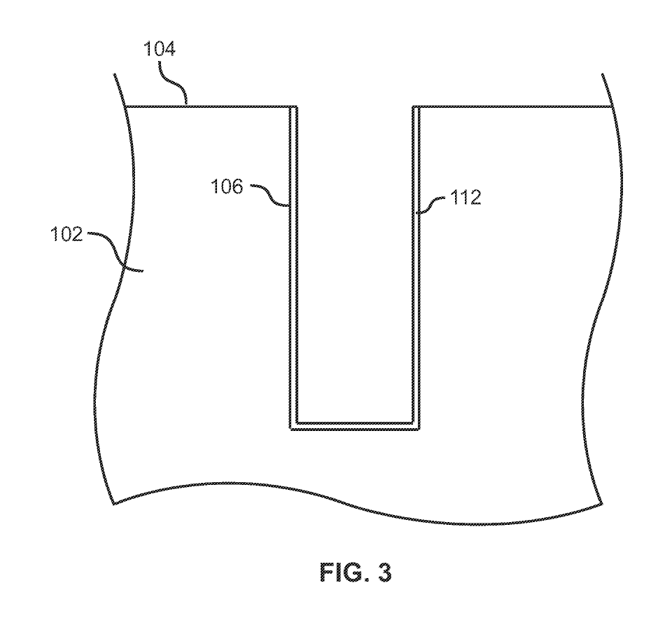

Referring to FIG. 3, a first barrier layer (or material) 112 is formed within the trench 106. The first barrier layer 112 may be made of any material suitable to provide a barrier against the diffusion of material between the trench body 102 and the other materials/layers formed within the trench 106 described below. In some embodiments, the first barrier layer 112 includes an oxide, such as aluminum oxide, or a nitride, such as silicon nitride, and may be formed using any suitable process, such as physical vapor deposition (PVD). As shown, the first barrier layer 112 may be formed on the sidewalls, as well as the bottom, of the trench 106. It should be noted that in some embodiments, the first barrier layer 112 is not utilized.

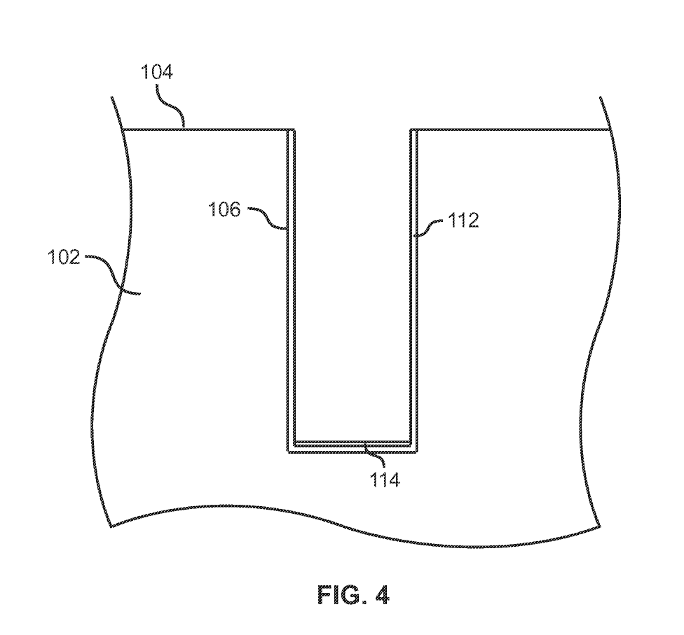

As shown in FIG. 4, in some embodiments, a supplemental layer 114 may be formed above the portion of the barrier layer 112 at the bottom of the trench 106. The supplemental layer 114 may be used to facilitate subsequent post-processing of non-ferroelectric residues after the formation of the ferroelectric material(s) described below.

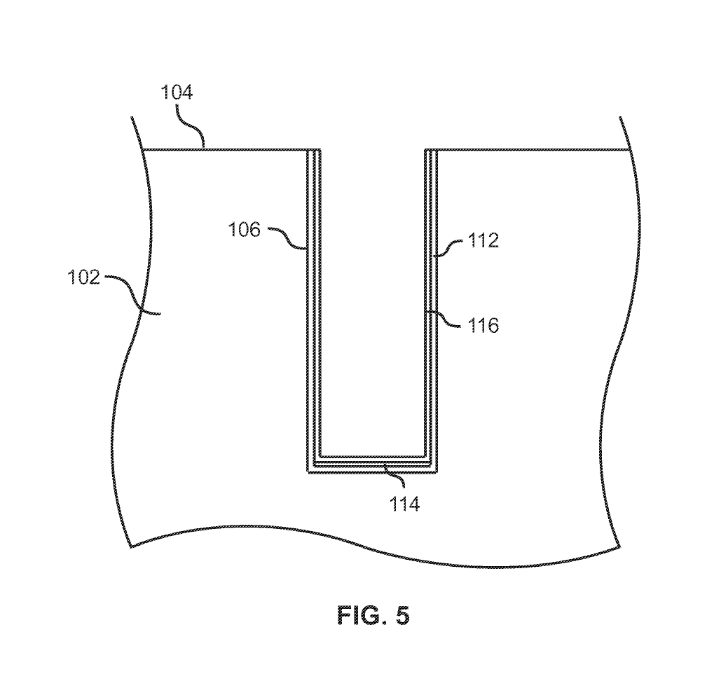

Referring now to FIG. 5, a layer of intended ferroelectric material is then deposited within the trench, over at least portions of the first barrier layer 112 on the sidewalls of the trench 106. In some embodiments, at least some of the intended ferroelectric material is also deposited above the supplemental layer 114 (i.e., if utilized). In some embodiments, the intended ferroelectric material is deposited as a layer of dielectric material (i.e., a dielectric layer) 116. The dielectric layer 116 may include a high-k dielectric material that includes hathium, zirconium, titanium, aluminum, yttrium, or a combination thereof. In some embodiments, the dielectric layer comprises hafnium oxide, zirconium oxide, a hafnium and/or zirconium oxide-based alloy, or a combination thereof. In some embodiments, the dielectric layer 116 is deposited using a method (e.g., atomic layer deposition (ALD)) that allows the processing temperature to be kept sufficiently low such that the material of the dielectric layer 116 is deposited in an amorphous state, such as between room temperature (e.g., about 25° C.) and about 100° C.

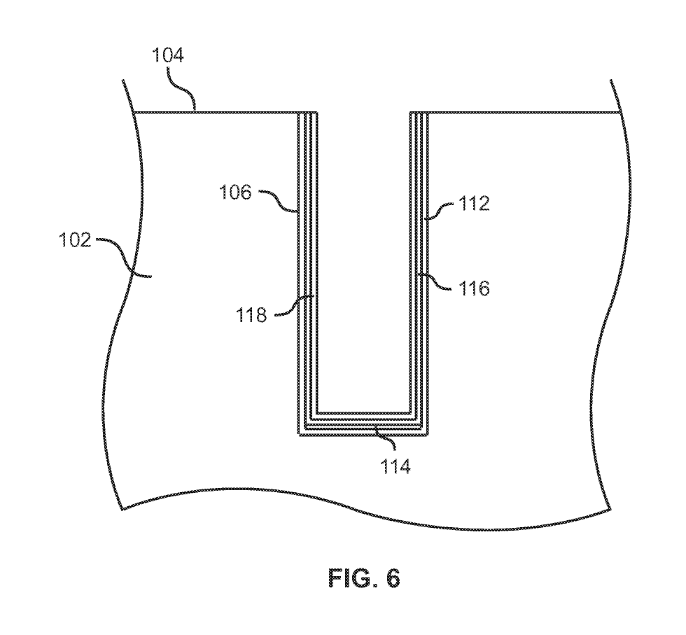

As shown in FIG. 6, a second barrier layer 118 is then formed within the trench 106, above the dielectric layer 116. The second barrier layer 118 may include the same material(s) used to form the first barrier layer (e.g., aluminum oxide or silicon nitride) and may similarly provide a barrier against the diffusion of material between the dielectric layer 116 and the filler material (described below). The second barrier layer 118 may also serve as an etch stop during the removal of the filler material and may be able to withstand extreme sheer (possibly undergoing irreversible transformations) to minimize the stress components coplanar to the film.

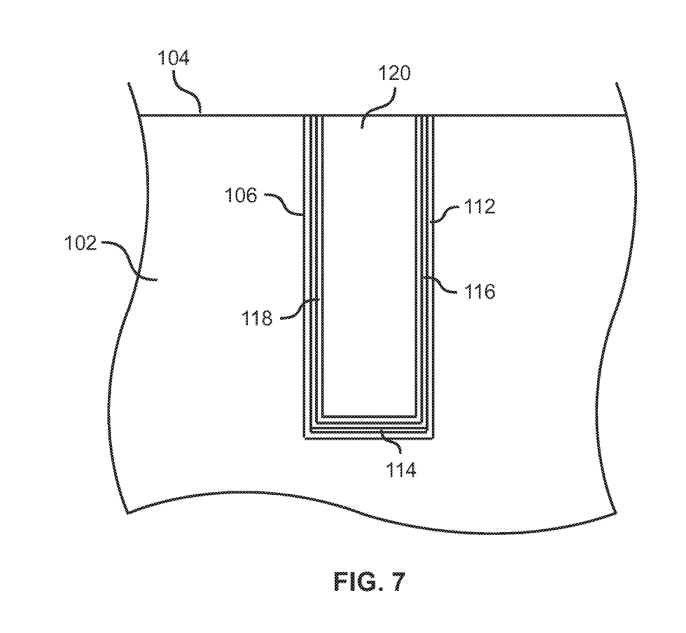

Referring now to FIG. 7, a filler material 120 is then deposited (or formed) within the trench 106 such that the trench 106 is then, at least in some embodiments, completely filled (e.g., the filler material 120 is deposited into and fills the previously unoccupied portion(s) of the trench 106). In some embodiments, the filler material 120 has a relatively high coefficient of linear thermal expansion (e.g., higher than that of the material of the trench body 102 and/or the dielectric layer 116). In some embodiments, the filler material 120 includes one or more metals, such as aluminum, magnesium, lead, etc., which may be deposited using any suitable process, such as a plating process, PVD, etc. In some embodiments, the filler material 120 includes an organic material, such as an organic polymer. Suitable organic polymers include polysulfones and polyimidines, as well as those mentioned below. The organic material may be deposited into the trench using, for example, any suitable polymerization method. In some embodiments, dyes and/or impurities may be added to the filler material 120 material to maximize light absorption, as described below.

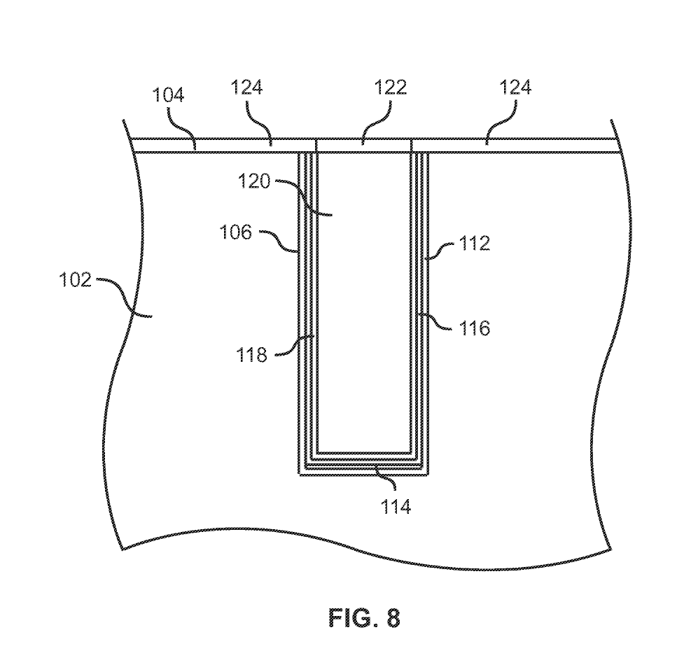

As shown in FIG. 8, in some embodiments, a transparent layer 122 and a non-transparent (or reflective) layer 124 are then formed at the upper surface 104 of the trench body 102. In the some embodiments, the transparent layer 122 is formed above the filler material 120 within the trench 106, while the non-transparent layer 124 is formed above the remaining portions of the trench body 102. In some embodiments, the transparent layer 122 includes (or is made of) a transparent material, such as silicon oxide. In addition to allowing light to pass therethrough (as described below), the transparent layer 122 may be used to ensure chemical and physical integrity of the filler material 120. In some embodiments, the non-transparent layer 124 includes a non-transparent, or reflective, material, such a metallic material (e.g., aluminum, tin, etc.). It should be noted that, in some embodiments, the transparent layer 112 and/or the non-transparent layer 124 may not be used.

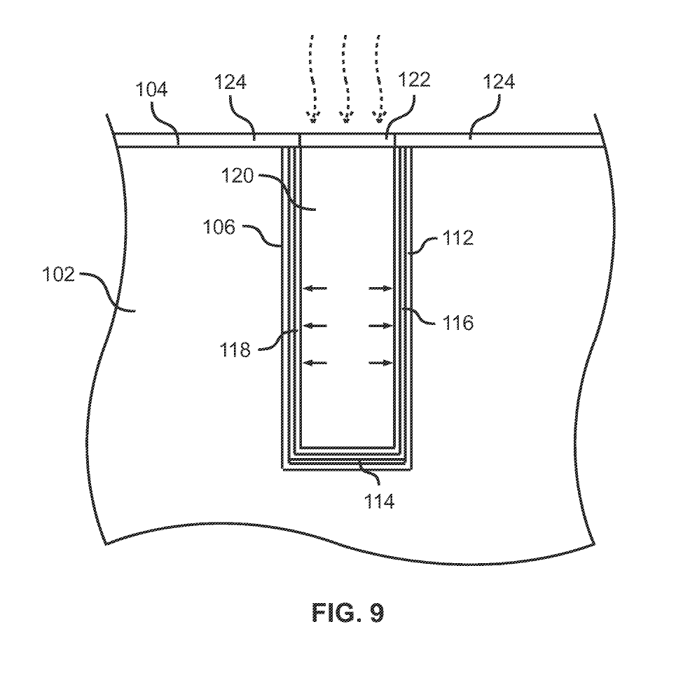

Referring now to FIG. 9, the filler material 120 is then expanded such that a stress is exerted on the dielectric layer 116. More specifically, in some embodiments, the filler material 120 is expanded in such a way that it expands faster than the trench body 102 and/or the dielectric layer 116. In some embodiments, this is performed by heating the structure such that the filler material 120 is heated more than, or faster than, the trench body 102 and/or the dielectric layer 116.

In some embodiments, such as those in which the filler material 120 includes an organic polymer, the filler material 120 is expanded by directing light (e.g., laser light) through the transparent layer 122 into the filler material 120. The wavelength of the light may be selected to maximize the absorption of the light by filler material 120 (e.g., corresponding to dyes or impurities added to the filler material).

In some embodiments, the light is infrared (IR) light with a wavelength(s) that matches the frequency of the known IR-active modes of the particular polymer used. For example, when benzene-based polymers, such as polyimidines or polysulfones, are used, a non-monochromatic light wavenumber can be selected either to fill in the window of about 3050 cm⁻¹ to about 3250 cm⁻¹ to target the C—H bond-stretching modes, or to fill in the window of about 600 cm⁻¹ to about 900 cm⁻¹ to target the C—H out-of-ring-plane bond-bending modes. When the IR-active frequencies of the polymer(s) used are known with high degree of accuracy, a narrow window (e.g. ˜1 cm⁻¹) may be selected around such frequencies.

In some embodiments, when the specific IR-active vibrational frequencies of the polymer(s) used are not known, or are otherwise sensitive to the environment and/or conditions (e.g., temperature, stress, etc.), the light may not be monochromatic. Rather, a distribution of wavelengths may be used that targets the window of typical frequencies of the relevant vibration type.

Still referring to FIG. 9, due to the relatively high coefficient of linear thermal expansion of the filler material 120, a substantial compressive stress is created across the dielectric layer 116 before the material is brought to the crystallization temperature. For example, when the filler material 120 includes perfluoroalkoxy (PFA), the filler material may have a coefficient of linear thermal expansion of about 130×10⁻⁶, while being able to withstand a 300° C. anneal. When polysulfone is used, the coefficient of linear thermal expansion may be about 56×10⁻⁶, while being able withstand a 190° C. anneal. When polybenzimidazole is used, the coefficient of linear thermal expansion may be about 23×10⁻⁶, while being able to withstand a 427° C. anneal. Thermoplastic polyimide may have a coefficient of linear thermal expansion of about 43×10⁻⁶, while being able to withstand a 320° C. anneal.

In some embodiments, while the filler material 120 is expanded (e.g., with the light still being directed through the transparent layer 122 and/or shortly thereafter), the device, or more particularly the dielectric layer 116 is heated (or annealed). In some embodiments, the heating process is performed using additional heat (e.g., in addition to that provided by the IR light), such as an anneal or rapid thermal process (RTP). In some embodiments, the heat required to crystallize the dielectric layer 116 is only provided by the light directed through the transparent layer 122. Because of the compressive stress applied to the dielectric layer 116 (i.e., before the dielectric layer 116 itself is heated substantially), a ferroelectric phase may be generated within the dielectric layer 116 at relatively low temperatures, such as less than about 1000° C., perhaps even less than about 400° C.

The temperature of the heating process (e.g., via IR light and/or anneal/RTP), T, and the trench width, W, (i.e., width 108 in FIG. 2) may be selected such that

W(LE_{f}−LEₘ) (T−Tᵣₒₒₘ)>>P_{cr}(W/E_{f}+d/Eₜₑ+L/W),

where LE_{f} is the linear coefficient of thermal expansion for the filler material 120, LEₘ is the linear coefficient of thermal expansion for the material of the trench body 102, d is the thickness of the dielectric layer 116, L is the smaller of trench height (i.e., height 110 in FIG. 2) and the distance to the adjacent trench (if any), P_{cr} is a critical pressure (e.g., about 3 GPa to about 10 GPa), and E_{f} and Eₜₑ are the Young moduli of the filler material 120 and the dielectric layer 116.

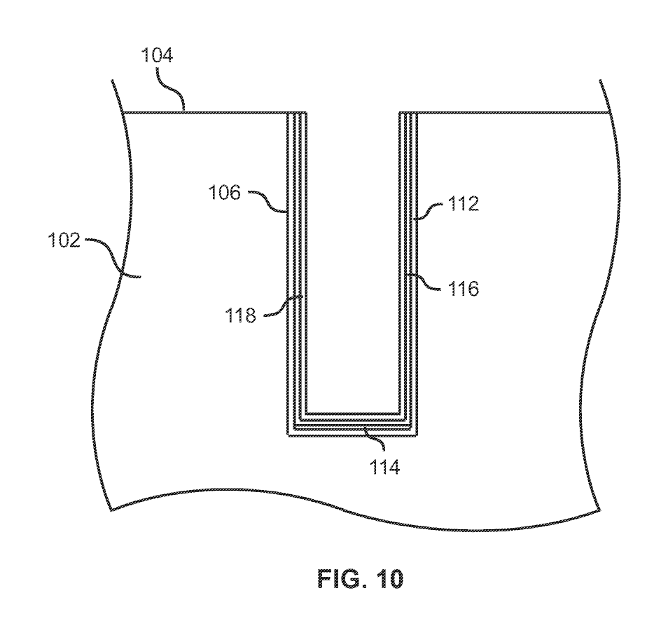

As shown in FIG. 10, after the generation of the ferroelectric material (or a ferroelectric phase within the dielectric layer 116), the filler material 120 (as well as the transparent layer 122 and/or the non-transparent layer 124, if used) is removed using, for example, an etching process. In some embodiments, additional suitable processing may be performed on the bottom of the trench (e.g., utilizing supplemental layer 114), where the ferroelectric material may not have formed.

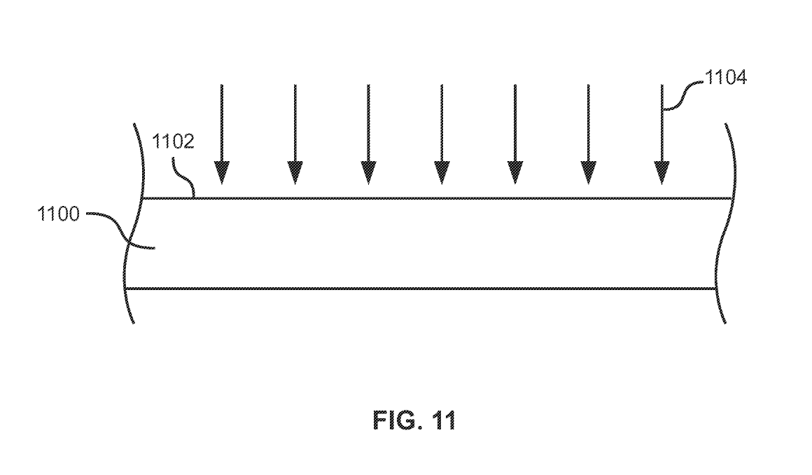

FIGS. 11-17 illustrate methods for forming a ferroelectric material, or generating a ferroelectric phase in a material, according to some embodiments. It should be understood that although specific number(s) of layers are shown and described in FIGS. 11-17, the number(s) of layers may vary in some embodiments.

Referring to FIG. 11, a substrate 1100 is provided. In some embodiments, the substrate 1100 includes (or is made of) a semiconductor material, such as silicon, germanium, and/or a “III-V” semiconductor material, such as gallium arsenide. The substrate 100 has an upper surface 1102 and a thickness (not shown) of, for example, between about 200 micrometers (μm) and about 400 μm.

Still referring to FIG. 11, in some embodiments, a surface treatment is performed on the upper surface 1102 of the substrate 1100. In some embodiments, the surface treatment is performed by exposing the upper surface to a plasma, as indicated by arrows 1104. In some embodiments, the surface treatment includes exposing the upper surface 1102 to nitrogen radicals (e.g., using a remote plasma source). The surface treatment may remove a native oxide that has formed on the upper surface 1102 of the substrate 1100.

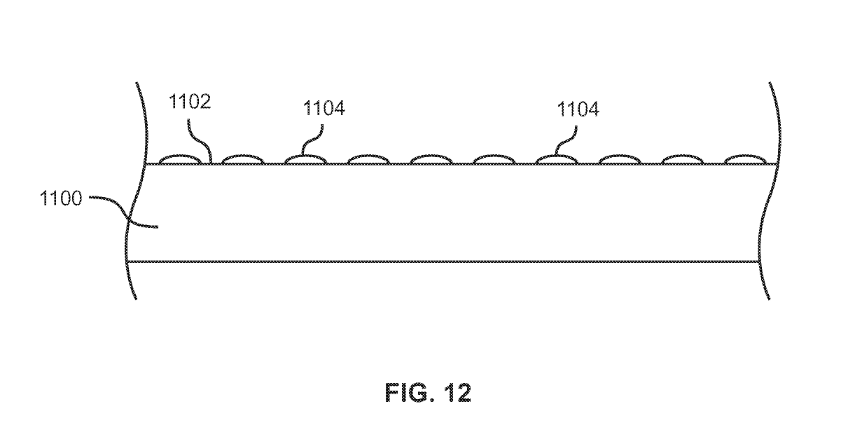

As shown in FIG. 12, a first layer is then formed above (e.g., on) the upper surface 1102 of the substrate 1100. In some embodiments, the first layer includes (or is made of) a high-k dielectric material, such as hafnium oxide, zirconium oxide, a hafnium and/or zirconium oxide-based alloy, yttrium oxide, titanium oxide, silicon oxide, or a combination thereof, which may or may not be doped during the deposition process. In some embodiments, the first layer includes a material that may be used to dope a high-k dielectric material, such as aluminum (e.g., aluminum oxide), titanium (e.g., titanium oxide), yttrium (e.g., yttrium oxide), and/or silicon (e.g., silicon oxide). In some embodiments, the first layer is formed using an ALD process that is tuned in such a way that the nucleation delay, as is commonly understood, is relatively high (e.g., higher compared to conventional ALD processes in which flat/non-textured/contiguous layers are formed) such that the first layer manifests as a series of “islands” 1104 (i.e., the first layer 1104 is non-contiguous). As will be appreciated by one skilled in the art, the nucleation delay of the ALD process may be increased by, for example, performing a surface treatment (such as the one described above) on the upper surface 1102 of the substrate before the first layer is formed, selecting particular precursors to form the layer, adjusting processing temperatures, etc. The islands 1104 may have the effect of providing the upper surface 1102 of the substrate 1100 (and/or the first layer) a textured or roughened topography.

In some embodiments, the texturing is providing by forming or depositing other structures on the upper surface 1102 of the substrate 1100, which may also be represented by the islands 1104 shown in FIG. 12. For example, in some embodiments, nanoparticles and/or carbon nanotubes are deposited and/or grown on the surface 1102. Nanoparticles (e.g., aluminum oxide) may be deposited using, for example, a sol-gel process. Carbon nanotubes may be grown on the surface 1102, using, for example a CVD process. The carbon nanotubes may be axially aligned or arranged in random networks.

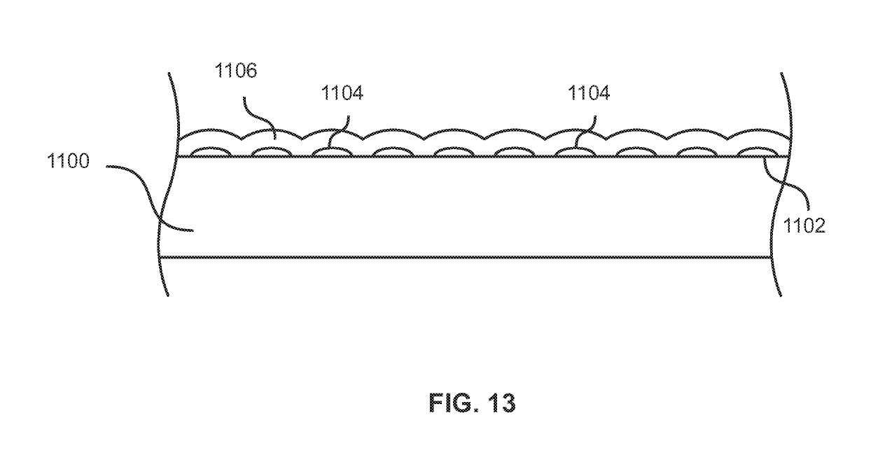

Referring now to FIG. 13, a second layer 1106 is then formed above (e.g., on) the first layer 1104. The second layer 1106 may be formed using, for example, ALD and be made of the same material(s) as the first layer 1104. In some embodiments, the second layer 1106 is formed using a convention ALD process (e.g., with a typical nucleation delay) such that the second layer 1106 is formed as a contiguous layer. In some embodiments, the second layer 1106 is deposited in a manner similar to the first layer 1104 (e.g., with a relatively high nucleation delay). As the material of the second layer 1106 is deposited onto the first layer 1104, it may conform to the contours provided by the islands such that a stress is exerted on the material of the second layer 1106. As is shown in FIG. 13, in some embodiments, an upper surface of the second layer 1106 is somewhat textured/contoured.

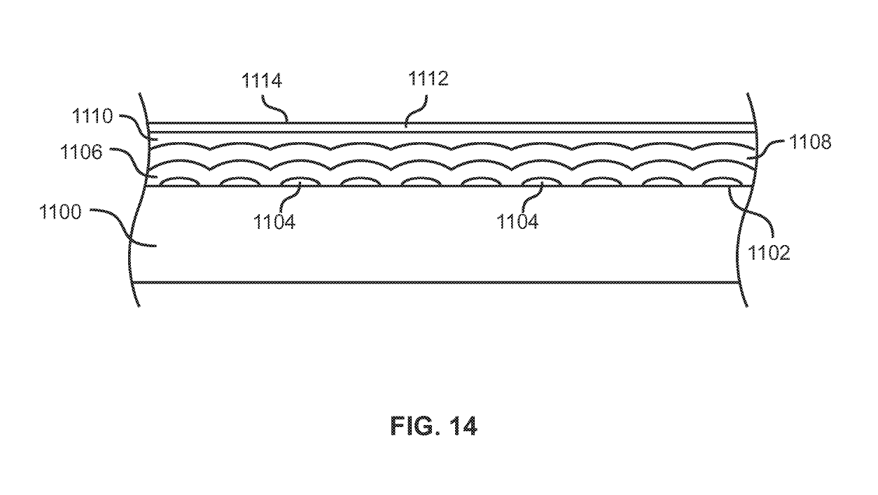

As shown in FIG. 14, in some embodiments, additional layers 1108, 1110, and 1112 may then be formed above the second layer 1106. The additional layers 1108, 1110, and 1112 may include the same materials as the first layer 1104 and the second layer 1106 and be formed using similar ALD processes, with either convention nucleation delays or relatively high nucleation delays. In some embodiments, layers 1108, 1110, and 1112 are formed using conventional ALD processes such that the texturing/contouring caused by the lower layers (e.g., the first layer 1104) is gradually “phased out.” Thus, in some embodiments, an upper surface 1114 of the upper-most layer (e.g., layer 1112) is substantially planar.

Although not shown, in some embodiments, the substrate 1100 and the layers 1104-1112 may then be heated or annealed to generate a ferroelectric phase in at least one of the layer 1104-1112. Due to the stress exerted on at least the second layer 1106 before the heating process, a ferroelectric phase may be generated within the material of the second layer 1106 at relatively low temperatures. The heating process may be performed at a temperature of, for example, less than 1000° C., such as less than about 400° C. During the crystallization of the layers 1106-1112, the ferroelectric phase of the second layer 1106 (i.e., the nanocrystals formed therein) may influence the crystallization of the other layers such that the entire stack takes on a ferroelectric phase. In other words, the second layer 1106 (and/or any other layers on which a stress is exerted before the annealing process) may serve as a template layer for the formation of a ferroelectric phase in the layers which are not stressed before the annealing process.

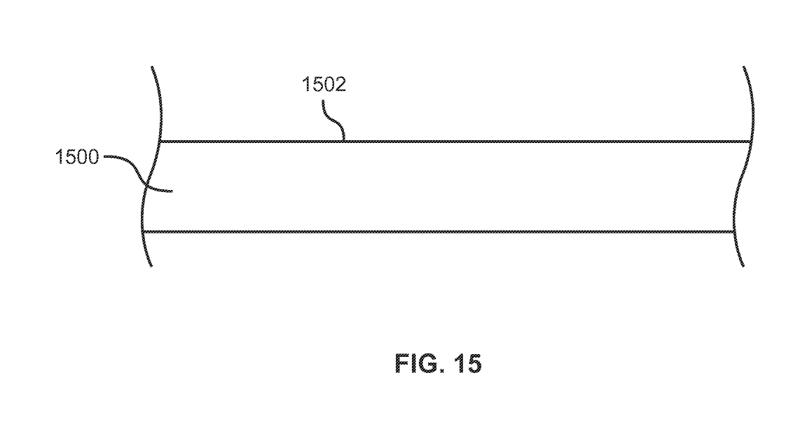

Referring now to FIGS. 15-17, a method similar to that of FIGS. 11-14 is shown. In FIG. 15, a substrate 1500 is provided, which may be similar to substrate 1100 described above. In some embodiments, a surface treatment is not performed on the substrate 1500 before the formation of the layers described below. As such, although not shown, the substrate 1500 may have a layer of native oxide (e.g., silicon oxide) that has formed on the upper surface 1502 thereof.

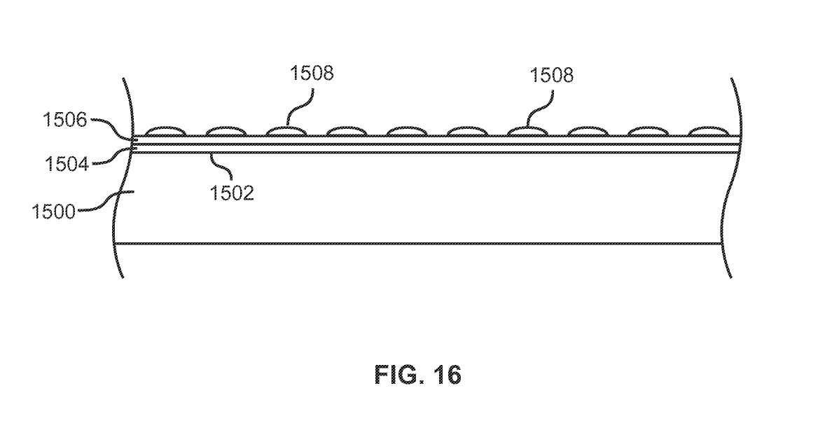

As shown in FIG. 16, layers 1504, 1506, and 1508 are then successively formed above the substrate 1500. Layers 1504, 1506, and 1508 may include the same materials described above (e.g., high-k dielectric materials and/or dopants) and be formed using ALD. In the depicted embodiments, layers 1504 and 1506 may be formed using conventional ALD processes such that layer 1504 and 1506 are substantially planar and contiguous. However, layer 1508 is formed using a relatively high nucleation delay such that it is non-contiguous and includes a series of islands (similar to layer 1104 described above).

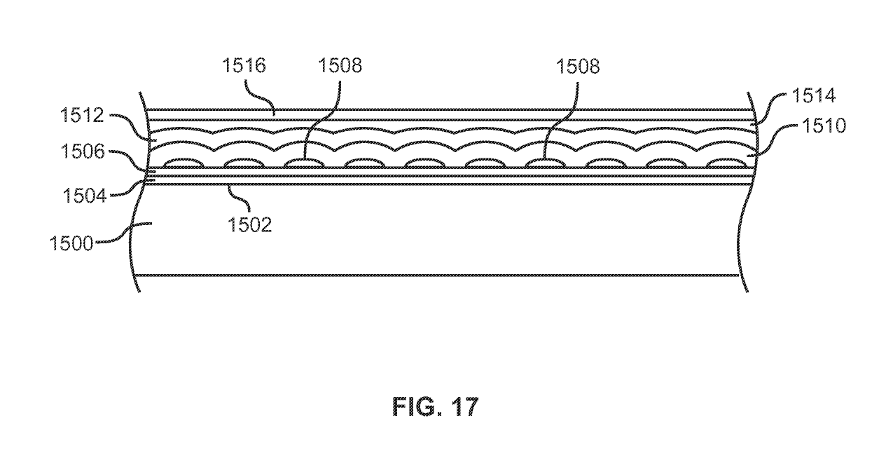

Referring now to FIG. 17, additional layers 1510, 1512, 1514, and 1516 are then successively formed above layer 1508. Layers 1510-1516 may include similar materials and be formed using the same methods as layers 1108-1112 described above. After the formation of layers 1510-1516, the substrate 1500 and the layers 1504-1516 may then be heated or annealed (e.g., at a temperature of less than about 1000° C., such as less than about 400° C.) to generate a ferroelectric phase in at least one of the layer 1504-1516, which may influence the crystallization of the remainder of the layers, in a manner similar to that described above.

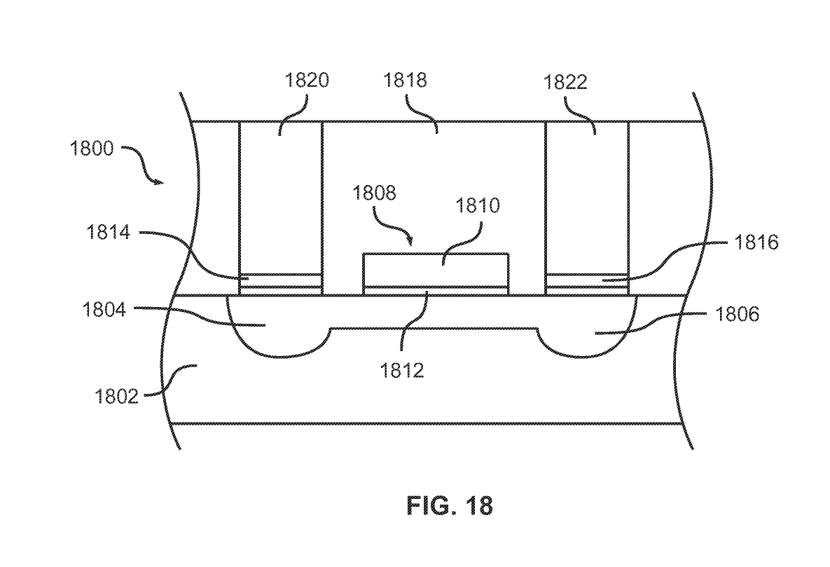

FIG. 18 illustrates a semiconductor device 1800 in which the ferroelectric material(s), or materials with ferroelectric phases, described above may be incorporated. In some embodiments, the semiconductor device 1800 is a metal-oxide-semiconductor field-effect transistor (MOSFET). In the depicted embodiment, the device 1800 is formed above, or on, a substrate 1802, such as those described above (e.g., a semiconductor substrate). The device 1800 includes a source region 1804, a drain region 1806, and a gate stack 1808 formed between the source region 1804 and the drain region 1806. The source region 1804 and the drain region 1806 may be formed in the substrate 1802 via, for example, implanting (or doping) N-type (or P-type) impurities into the substrate 1802, and as shown, may diffuse through the substrate 1802 to a region below the gate stack 1808. The gate stack 1808 may include a conductive gate 1810 (e.g., made of polycrystalline silicon) formed above a gate dielectric layer 1812. In some embodiments, the gate dielectric layer 1812 includes, or is made of, ferroelectric materials, such as those described above.

The device 1800 also includes contacts 1814 and 1816 respectively formed above the source region 1804 and the drain region 1806. Further, the device 1800 includes a dielectric material (e.g., an interlayer dielectric layer) 1818 formed (e.g., via PVD, etc.) above the substrate 1802 through which conductive vias (e.g., made of copper) 1820 and 1822 have been formed, which are electrically connected to the contacts 1814 and 1816, respectively.

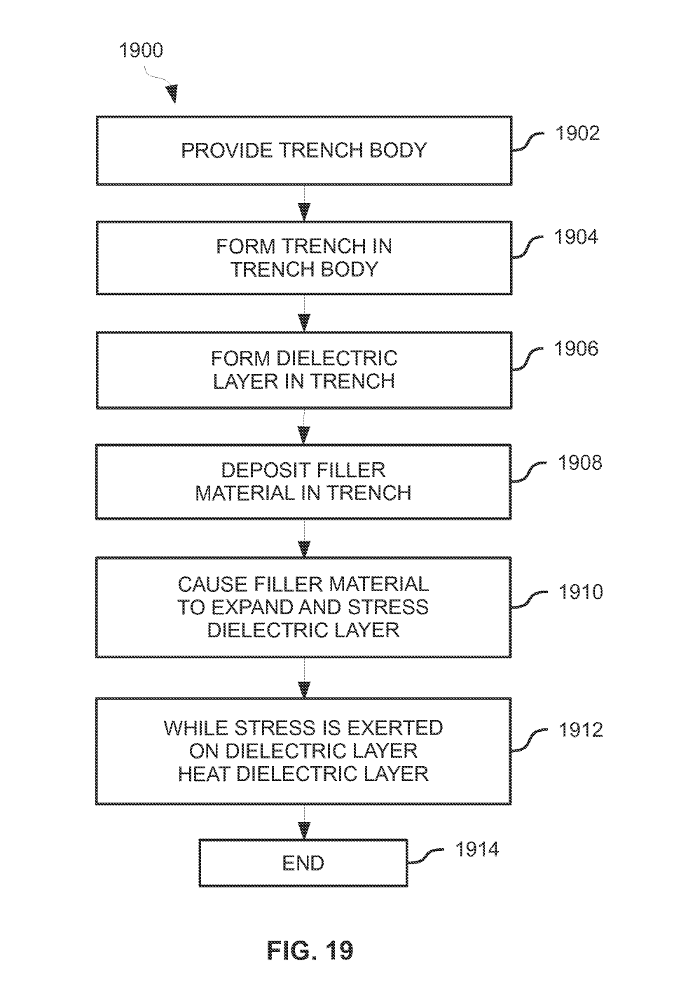

FIG. 19 illustrates a method 1900 for forming a ferroelectric material, or generating a ferroelectric phase in a material, according to some embodiments. At block 1902, a trench body (or trench layer) is provided. The trench body may include a material with a relatively low coefficient of linear thermal expansion. In some embodiments, the trench body includes a semiconductor material, such as silicon, or a dielectric material, such as silicon oxide or glass.

At block 1904, a trench is formed in the trench body. The trench may have a relatively high aspect ratio (i.e., a larger height than width) and depth that is relatively small compared to a thickness of the trench body. In some embodiments, a (first) barrier layer (e.g., aluminum oxide or silicon nitride) is formed in the trench before any other layer/materials are deposited in the trench.

At block 1906, a dielectric layer is formed within the trench. The dielectric layer may include a high-k dielectric material, such as hafnium oxide, zirconium oxide, a hafnium and/or zirconium oxide-based alloy, or a combination thereof. In some embodiments, the dielectric layer is deposited using a method that allows the processing temperature to be kept sufficiently low such that the material of the dielectric layer is deposited in an amorphous state. In some embodiments, a (second) barrier layer (e.g., aluminum oxide or silicon nitride) is formed in the trench, over the dielectric layer.

At block 1908, a filler material is then deposited in the trench. In some embodiments, the filler material has a relatively high coefficient of linear thermal expansion (e.g., high than that of the trench body and/or the dielectric layer). In some embodiments, the filler material includes one or more metals, such as aluminum, magnesium, lead, etc., which may be deposited using any suitable process, such as plating process, PVD, etc. In some embodiments, the filler material includes an organic material, such as an organic polymer. Suitable organic polymers include polysulfones and polyimidines. The organic material may be deposited into the trench using, for example, any suitable polymerization method. Although not shown in FIG. 19, in some embodiments, a transparent layer (e.g., silicon oxide) is formed at an upper surface of the trench body, above the filler material, and a non-transparent layer (e.g., a metal) is formed is formed above the remaining portions of the trench body.

At block 1910, the filler material is then expanded such that a stress (or force) is exerted on the dielectric layer. More specifically, in some embodiments, the filler material is expanded in such a way that it expands faster than the trench body 102 and/or the dielectric layer 116. In some embodiments, this is performed by heating the structure such that the filler material 120 is heated more than, or faster than, the trench body 102 and/or the dielectric layer 116. In some embodiments, such as those in which the filler material includes an organic polymer, the filler material is expanded by directing light (e.g., IR light) into the filler material. The wavelength of the light may be selected to maximize the absorption of the light by filler material 120.

At block 1912, while the stress is exerted on the dielectric layer, the device, or more particularly the dielectric layer, is heated (or annealed) to crystallize the material of the dielectric layer. In some embodiments, the heating process is performed using additional heat (e.g., in addition to that provided by the IR light), such as an anneal or rapid thermal process (RTP). In some embodiments, the heat required to crystallize the dielectric layer is only provided by the IR light directed into the filler material. Because of the compressive stress applied to the dielectric layer 116 (i.e., before the dielectric layer itself is substantially heated), a ferroelectric phase may be generated within the dielectric layer at relatively low temperatures (e.g., less than about 500° C.). At block 1914, the method 1900 ends.

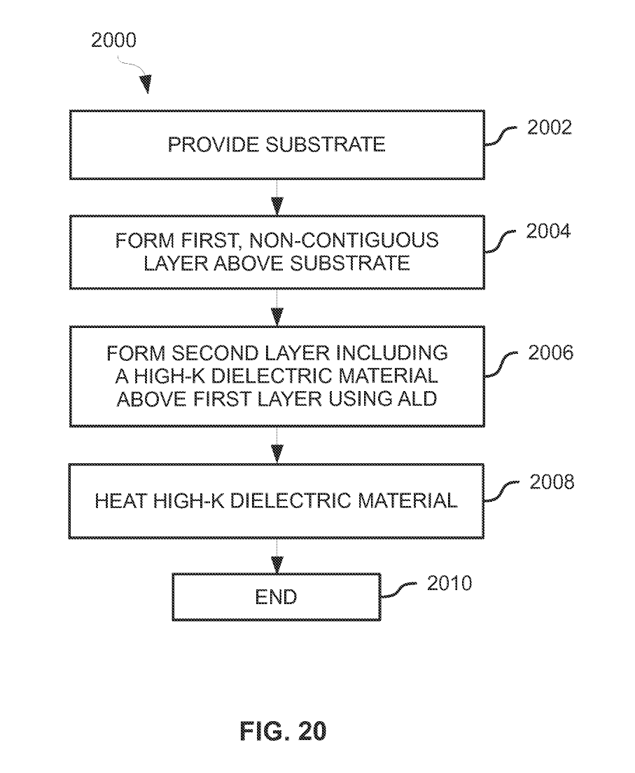

FIG. 20 illustrates a method for forming a ferroelectric material, or generating a ferroelectric phase in a material, according to some embodiments. At block 2002, a substrate is provided. In some embodiments, the substrate includes a semiconductor material, such as silicon, germanium, and/or a III-V semiconductor material, such as gallium arsenide.

At block 2004, a first layer is formed above the substrate. In some embodiments, the first layer is non-contiguous. For example, in some embodiments, the first layer made be formed using and ALD process with a relatively high nucleation decay such that the first layer manifests as a series of islands. In some embodiments, the first layer includes (or is made of) a high-k dielectric material, such as hafnium oxide, zirconium oxide, a hafnium and/or zirconium oxide-based alloy, or a combination thereof. In some embodiments, the first layer includes a material that may be used to dope a high-k dielectric material, such as aluminum (e.g., aluminum oxide), titanium (e.g., titanium oxide), yttrium (e.g., yttrium oxide), and/or silicon (e.g., silicon oxide). In some embodiments. In some embodiments, the first layer includes nanoparticles (e.g., aluminum oxide) and/or carbon nanotubes that are deposited and/or grown on the substrate (or any layers formed thereon before the formation of the first layer).

At block 2006, a second layer is formed above the first layer. The second layer may include a high-k dielectric material such as hafnium oxide, zirconium oxide, a hafnium and/or zirconium oxide-based alloy, or a combination thereof. In some embodiments, the second layer is formed using ALD. In some embodiments, the second layer is formed using a convention ALD process (e.g., with a typical nucleation delay) such that the second layer is formed as a contiguous layer. As the material of the second layer is deposited onto the first layer, it may conform to the contours, or texture, provided by the first layer such that a stress is exerted on the material of the second layer. In some embodiments, additional layers may then be formed above the second layer. The additional layers may include the same materials as the first layer 1104 and the second layer 1106 and be formed using similar ALD processes, with either convention nucleation delays or relatively high nucleation delays.

At block 2008, the high-k dielectric material of the second layer is heated or annealed to generate a ferroelectric phase in at least one of the layers formed. Due to the stress exerted on at least the second layer before the heating process, a ferroelectric phase may be generated within the material of the second layer at relatively low temperatures. The heating process may be performed at a temperature of, for example, less than 1000° C., such as less than about 400° C. During the crystallization of the layers, the ferroelectric phase of the second layer (i.e., the nanocrystals formed therein) may influence the crystallization of the other layers such that the entire stack takes on a ferroelectric phase. In other words, the second layer (and/or any other layers on which a stress is exerted before the annealing process) may serve as a template layer for the formation of a ferroelectric phase in the layers which are not stressed before the annealing process. At block 2010, the method ends.

Thus, in some embodiments, methods for forming a ferroelectric material are provided. A trench body is provided. A trench is formed in the trench body. A dielectric material is deposited within the trench. A filler material is deposited within the trench over the dielectric material. The filler material is caused to expand (e.g., heated) such that a stress is exerted on the dielectric material. While the stress is exerted on the dielectric material, the dielectric material is heated to generate a ferroelectric phase within the dielectric material.

In some embodiments, methods for forming a ferroelectric material are provided. A trench body is provided. A trench is formed in the trench body. A high-k dielectric material is deposited within the trench. The high-k dielectric material includes at least one of hafnium oxide, zirconium oxide, or a combination thereof. A filler material is deposited within the trench over the high-k dielectric material. The filler material includes a polymer. The filler material is caused to expand (e.g., heated) such that a stress is exerted on the high-k dielectric material. The causing of the filler material to expand includes directing light into the filler material. While the stress is exerted on the high-k dielectric material, the high-k dielectric material is heated to generate a ferroelectric phase within the high-k dielectric material.

In some embodiments, methods for forming a ferroelectric material are provided. A substrate is provided. A first layer is formed above the substrate. The first layer is non-contiguous. A second layer is formed above the first layer using atomic layer deposition (ALD). The second layer includes a high-k dielectric material. The high-k dielectric material is heated to generate a ferroelectric phase within the high-k dielectric material.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a ferroelectric material, the method comprising:
providing a trench body;
forming a trench in the trench body;
depositing a dielectric material within the trench;
depositing a filler material within the trench over the dielectric material;
heating the filler material such that a stress is exerted on the dielectric material; and
while the stress is exerted on the dielectric material, heating the dielectric material to generate a ferroelectric phase within the dielectric material.

2. The method of claim 1, wherein the dielectric material comprises a high-k dielectric material, the high-k dielectric material comprising at least one of hathium, zirconium, titanium, aluminum, yttrium, or a combination thereof.

3. The method of claim 2, wherein the high-k dielectric material comprises at least one of hafnium oxide, zirconium oxide, or a combination thereof.

4. The method of claim 2, wherein the filler material has a coefficient of thermal expansion that is higher than a coefficient of thermal expansion of the material of the trench body.

5. The method of claim 4, wherein the coefficient of thermal expansion of the filler material is higher than a coefficient of thermal expansion of the high-k dielectric material.

6. The method of claim 5, wherein the filler material comprises a metallic material or a polymer.

7. The method of claim 6, wherein the filler material comprises a metallic material, wherein the metallic material comprises at least one of aluminum, magnesium, lead, or a combination thereof.

8. The method of claim 6, wherein the filler material comprises a polymer, wherein the polymer comprises at least one of a polysulfone, a polyimidine, or a combination thereof.

9. The method of claim 6, wherein the trench body comprises at least one of silicon, silicon oxide, borosilicate, or a combination thereof.

10. The method of claim 9, wherein the heating of the filler material comprises directing light into the filler material.

11. A method for forming a ferroelectric material, the method comprising:
providing a substrate;
forming a first layer above the substrate, wherein the first layer is non-contiguous;
forming a second layer above the first layer using atomic layer deposition (ALD), wherein the second layer comprises a high-k dielectric material; and
heating the high-k dielectric material to generate a ferroelectric phase within the high-k dielectric material.

12. The method of claim 11, wherein the first layer is formed using ALD, wherein a nucleation delay for the ALD process used to form the first layer is higher than a nucleation delay for an ALD process in which a contiguous layer is formed using the same material as the first layer.

13. The method of claim 12, wherein each of the first layer and the second layer comprises a high-k dielectric material, wherein the high-k dielectric material of each of the first layer and the second layer comprises at least one of hathium, zirconium, titanium, aluminum, yttrium, or a combination thereof.

14. The method of claim 11, wherein the first layer comprises at least one of nanoparticles, carbon nanotubes, or a combination thereof.

15. The method of claim 11, wherein the heating of the high-k dielectric material comprises heating the high-k dielectric material to a temperature less than 1000° C.

16. The method of claim 11, wherein the forming of the first layer comprises exposing an upper surface of the substrate to a plasma.

17. The method of claim 12, wherein the second layer is formed using ALD, wherein a nucleation delay for the ALD process used to form the second layer is higher than a nucleation delay for an ALD process in which a contiguous layer is formed using the same material as the second layer.

18. The method of claim 12, further comprising forming at least a third layer above the second layer, wherein the at least a third layer is formed using ALD.

19. The method of claim 12, further comprising forming at least a third layer above the substrate, wherein the at least a third layer is formed using ALD and the first layer is formed above the at least a third layer.

20. The method of claim 11, wherein the substrate comprises at least one silicon, germanium, gallium arsenide, or a combination thereof.
